(19) United States
(12) Patent Application Publication
(10) Pub. No.: US 2012/0223202 A1
(43) Pub. Date: Sep. 6, 2012

(54) MOUNTING APPARATUS FOR STORAGE DEVICE

(75) Inventors: YUN-LUNG CHEN, Tu-Cheng (TW); LIANG-CHIN WANG, Tu-Cheng (TW); JIAN HU, Wuhan City (CN); YU-MING XIAO, Wuhan City (CN); JUN WANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/294,386

(22) Filed: Nov. 11, 2011

(30) Foreign Application Priority Data
Mar. 2, 2011 (CN) 201110049881.2

(51) Int. Cl. H05K 7/00; F16M 13/00

(52) U.S. Cl. 248/309.1

(57) ABSTRACT

A mounting apparatus includes an enclosure and a mounting device. The enclosure defines a mounting hole. The mounting device includes a receiving member, an engaging member, an engaging rod, and a drive member moveably received in the receiving member. A positioning slot and a cutout are defined in the receiving member. The engaging member includes an engaging block, and the engaging block, abutting the drive member, is received in the positioning slot. A resilient member surrounds the engaging rod. The drive member biases the engaging block to slide in the positioning slot. The resilient component is deformed, and the engaging rod extends through the mounting hole and is received in an securing hole of a storage device; when the engaging block is disengaged from the positioning slot, the drive member is rotated relative to the receiving member, and the engaging block is engaged in the cutout.

### BACKGROUND

1. Technical Field

The present disclosure relates to mounting apparatuses, more particularly to a mounting apparatus for a storage device.

2. Description of Related Art

A typical personal computer includes data storage devices, such as hard disk drives (HDDS), floppy disk drives, and compact disc-read only memories (CD-ROMS) drives. Conventionally, the data storage devices are attached to a computer enclosure chassis with screws. A tool such as a screwdriver is used to fasten or unfasten the screws when mounting or removing the data storage devices. Such operations are laborious and time-consuming.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partially exploded, cutaway view of a mounting apparatus and a storage device in accordance with an embodiment.

FIG. 2 is an exploded, isometric view of a mounting device of the mounting apparatus in accordance with an embodiment.

FIG. 3 is an isometric view of a drive member of the mounting apparatus in accordance with an embodiment.

FIG. 4 is an assembly view of FIG. 1.

FIG. 5 is a cross section, cutaway view of FIG. 3, and the mounting device is located in an unlocked position.

FIG. 6 is similar to FIG. 4, but the mounting device is located in a locked position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

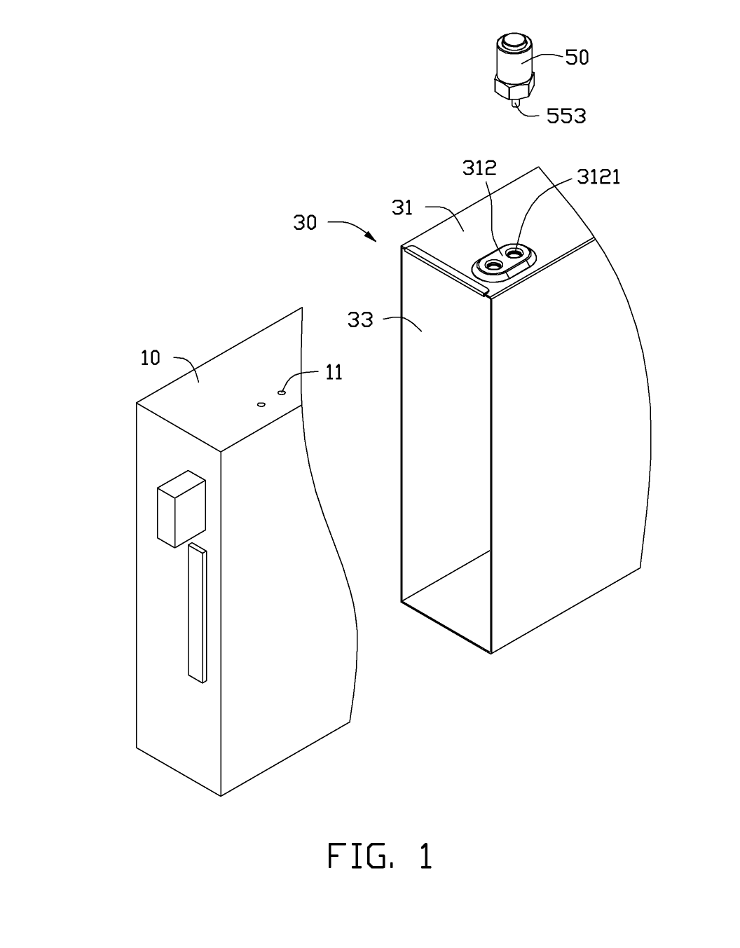

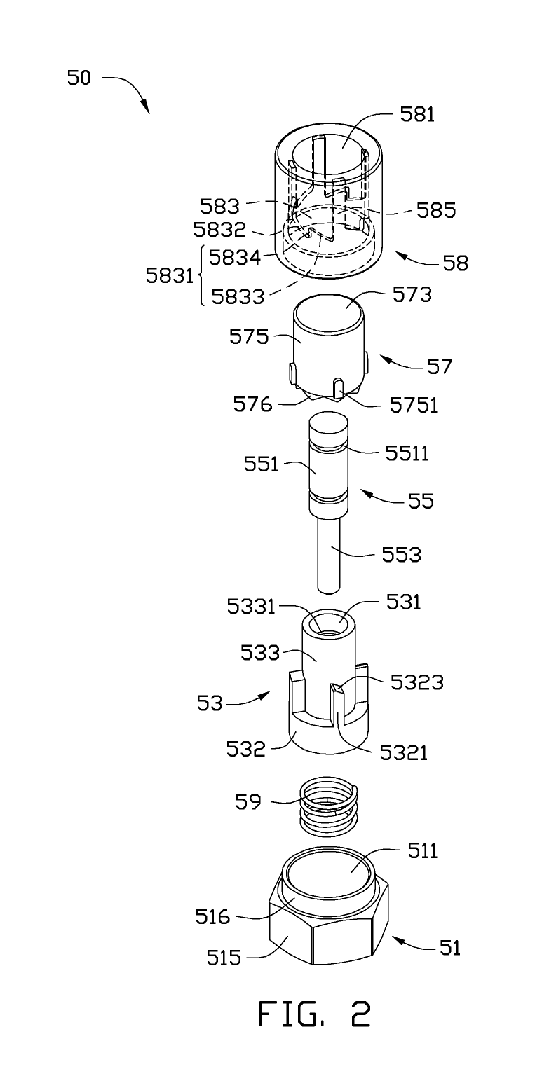

Referring to FIGS. 1 and 2, a mounting apparatus in accordance with an embodiment includes an enclosure 30 and a mounting device 50 attached to the enclosure 30. In one embodiment, a storage device 10 is received in the enclosure 30 and defines two securing holes 11. The storage device 10 can be hard disk drives (HDDS), floppy disk drives, and compact disc-read only memories (CD-ROMS) drive, for example.

The enclosure 30 includes a top panel 31. A protrusion 312 protrudes from the top panel 31 and defines two mounting holes 3121. Each mounting hole 3121 corresponds to each securing hole 11 and has an inner screw thread. An opening 33 is defined in the enclosure 30 for the storage device 10 to be inserted in or out of the enclosure 30.

Referring to FIG. 2, the mounting device 50 includes a mounting member 51, an engaging member 53, an engaging rod 55, a drive member 57, a receiving member 58, and a resilient member 59. The engaging member 53 is engaged with the mounting member 51, and the engaging rod 55 is moveably engaged with the mounting member 51 and the engaging member 53. The drive member 57 is mounted to the engaging rod 55. The receiving member 58 receives the drive member 57, and a resilient member 59 surrounds the engaging rod 55.

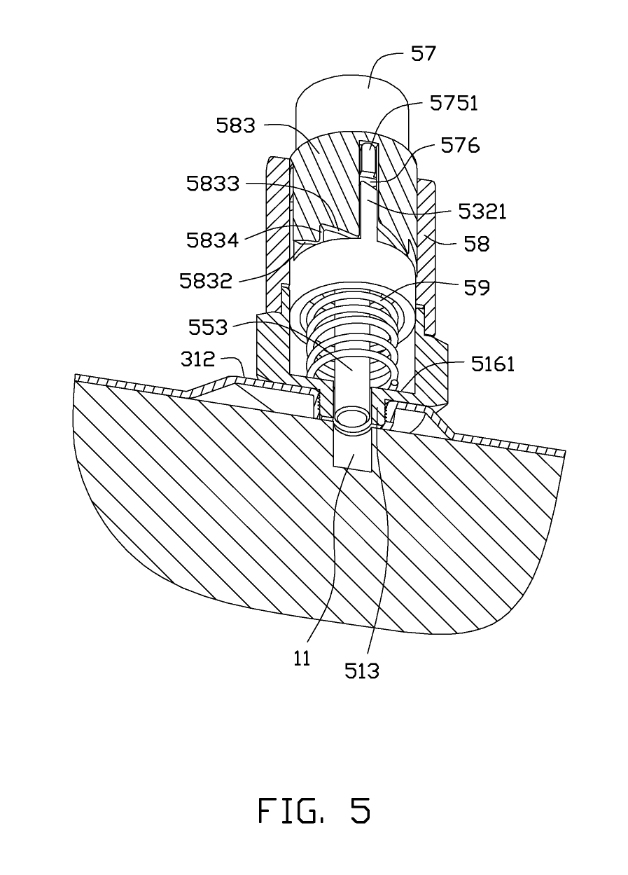

The mounting member 51 defines a through hole 511 and includes a mounting portion 513 (shown in FIG. 5), a base portion 515, and an extending portion 516. The mounting portion 513 is externally threaded. In one embodiment, the through hole 511 extends through the mounting portion 513, the base portion 515, and the extending portion 516. The base portion 515 is a hexagon, and a supporting portion 5161 (see FIG. 5) is located on the inner surface of the mounting member 51 and connected to the extending portion 516 and the base portion 515.

The engaging member 53 defines an engaging hole 531 and includes a base 532 and a retaining portion 533 connected to the base 532. In one embodiment, the base 531 and the retaining portion 533 are circular, and a diameter of the base 531 is greater than that of the retaining portion 533. Four engaging blocks 5321 extend from a top surface of the base 531 and are attached to an outer surface of the retaining portion 533. A slanted surface 5323 is defined in each of the four engaging blocks 5321. In one embodiment, a distance between every adjacent two engaging blocks 5321 is substantially equal to each other, and an extending direction of each slanted surface 5323 is about the same. Two sidesteps 5331 are defined in an inner surface of the retaining portion 533.

The engaging rod 55 includes a head 551 and a post 553 connected to the head 551. Two concave slots 5511, corresponding to the two sidesteps 5331, are defined in an outer surface of the head 551. In one embodiment, a diameter of the head 551 is greater than that of the post 553.

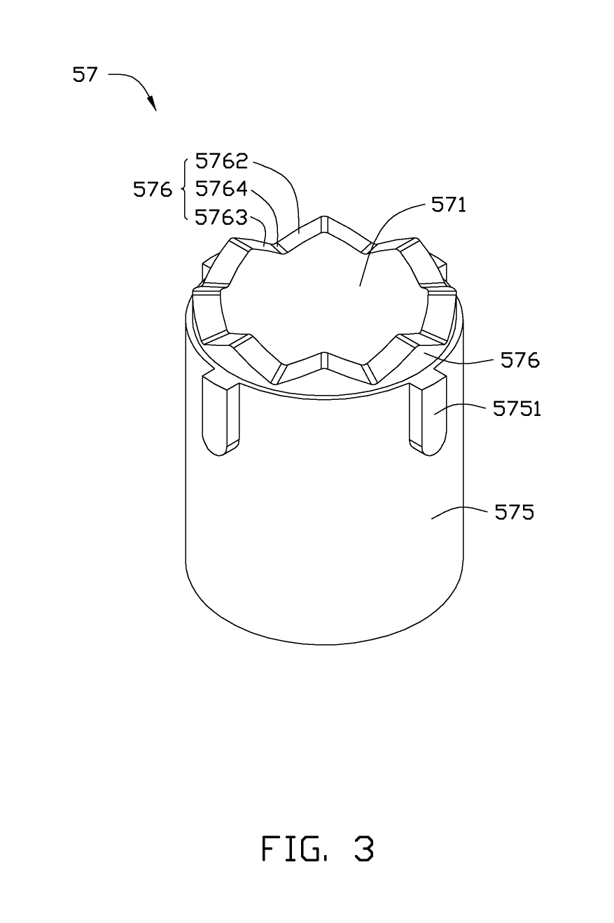

Referring to FIGS. 2 and 3, the drive member 57 includes a bottom plate 571, a top plate 573, and a side plate 575 connected to the bottom plate 571 and the top plate 573. In one embodiment, the drive member 57 includes a circular cross-section. A resisting portion 573 extends from the bottom plate 571, and a plurality of driving portions 576 are defined in the resisting portion 573. Each driving portion 576 includes a first slanted edge 5762 and a second slanted edge 5763. A stopping portion 5764 is connected to the first and second slanted edge 5762, 5763. The first slanted edge 5762 and the second slanted edge 5763 define an obtuse angle therebetween. In one embodiment, a length of the first slanted edge 5762 is substantially equal to that of the second slanted edge 5763, and an extending direction of each first slanted edge 5762 is about the same as that of each engaging block 5321. Four protruding blocks 5751 protrude from an outer surface of the side plate 575, and each protruding block 5751 is connected to the bottom plate 571.

Referring to FIG. 2, the receiving member 58 defines a receiving hole 581 and includes four positioning blocks 583 attached to an inner surface of the receiving member 58. A positioning slot 585 is defined between every two adjacent positioning blocks 583. Each positioning block 583 defines a cutout 5831 and a transition edge 5832. The cutout 5831 includes an oblique edge 5833 and a connecting edge 5834 connected to the transition edge 5832. An extending direction of the oblique edge 5833 is the same as that of each first slanted edge 5762. In one embodiment, a vertical length of the positioning slot 585 is shorter than that of the side plate 57, and a length of the oblique edge 5833 is substantially equal to a summation length of the first and second slanted edges 5762, 5763.

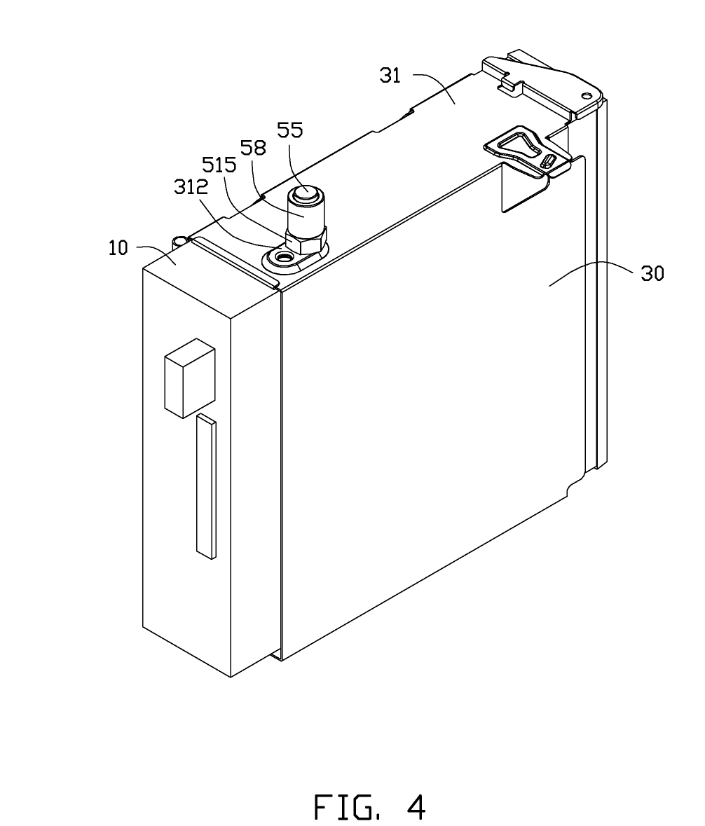

Referring to FIGS. 4-6, in assembly, the mounting portion 513 is engaged in one of the two mounting holes 3121. The engaging rod 55 is moved downward and extends through the engaging hole 531. The sidesteps 5331 are engaged in the concave slots 551 to secure the engaging rod 55 to the engaging member 53. The resilient member 59 surrounds the post 553. The base 532 is received in the extending portion 516, and the post 553 extends through the though hole 551. The resilient member 59 is thus resisting against the supporting portion 5161.

The drive member 57 is moved upward and received in the receiving hole 581, and the four protruding blocks 5751 are slidably received in the corresponding four positioning slots 585. The receiving member 58 and the drive member 57 are moved downward. The four engaging blocks 5321 are adjacent to an entrance of each of the corresponding four positioning slots 585, and the slanted surface 5323 of each engaging block 5321 abuts the first slanted edge 5762 and away from the stopping portion 5764. The receiving member 58 and the drive member 57 are further moved downward, and the engaging blocks 5321, abut the first slanted surface 5323, driving the four protruding blocks 5751 to slide in the four positioning slots 585, until the four protruding blocks 5751 are positioned on a top end of the four positioning slots 585. In the unlocked position (shown in FIG. 5), the resilient component 59 is in an original state, the post 553 is received in the through hole 511, each engaging block 5321 abuts the first slanted edge 5762 and away from the stopping portion 5764, and the drive member 57 is exposed out of the receiving member 58.

The storage device 10 is received in the enclosure 30 from the opening 33. One of the two securing holes 11 is aligned with one of the two mounting holes 3121. The drive member 57 is pressed downward towards the receiving hole 581, and the first slanted edge 5762, 5761 drives the four engaging blocks 5321 to move downward. The resilient component 59 is deformed, and the post 553 extends though the through hole 511 and is inserted into the securing hole 11.

When the four engaging blocks 5321 disengage from the corresponding positioning blocks 585 and reach a first end, away from the connecting edge 5834, of the oblique edge 5833, the drive member 57 is completely received in the receiving hole 581, and the resilient component 59 is deformed. In the middle position, the drive member 57 is received in the receiving member 58. The resilient component 59 is deformed, the engaging block 5321 is located the first second end of the oblique edge 5833, and the engaging rod 553 extends through the through hole 511 and the mounting hole 3121, to engage in the securing hole 11 of the storage device 10.

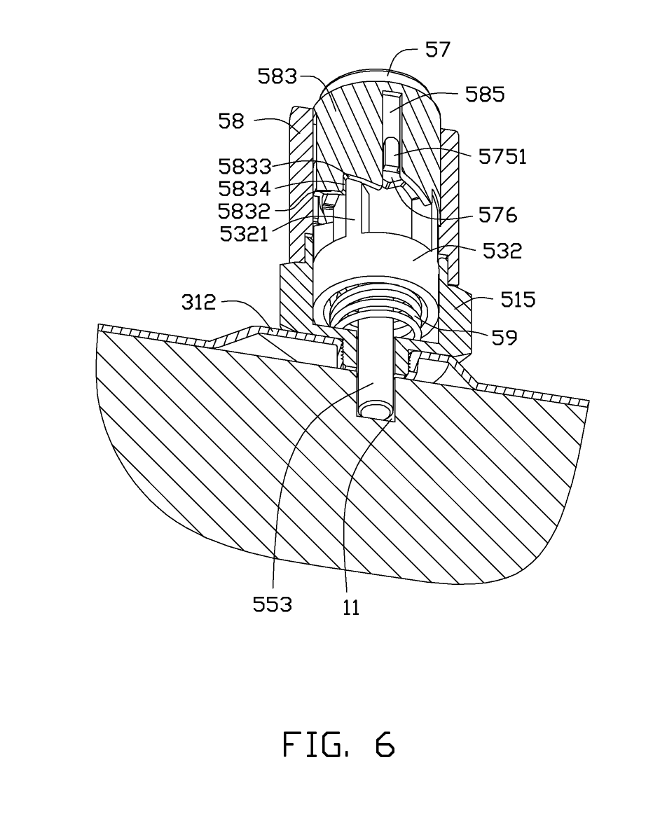

The four engaging blocks 5321 are disengaged from the four positioning blocks 583, and the engaging member 53 and the engaging rod 55 are together rotated about an axis defined by the engaging rod 55, towards the cutout 5831 clockwise, by the first slanted edge 5762. The engaging blocks 5321 are synchronously rotated from the first slanted edge 5762 to the second slanted edge 5763, and synchronously rotated towards the cutouts 5831 along the oblique edge 5833, until passing though the second slanted edge 5763 and abut a next (second) adjacent first slanted edge 5762. The engaging blocks 5321 are thus clipped in the corresponding cutouts 5831 and is located on a second end of the oblique edge 5833, to prevent the post 553 from disengaged from the securing hole 11. Synchronously, the resilient component 59 is released a little, to move the engaging member 53 upward a distance substantially equal to a vertical length of the connecting edge 5834. Therefore, the engaging member 53 can move the drive member upward to be exposed out of the receiving member 58. In this locked position (shown in FIG. 6), the resilient component 59 is deformed, the post 553 extends through the through hole 511 and is received in the securing hole 11, and the engaging blocks 5321 are clipped in the cutout 5831.

In disassembly of the storage device 10, the drive member 57 is pressed downward, to move the engaging member 53 downward. The resilient component 59 is deformed, and the engaging blocks 5321 are disengaged from the cutouts 5831. When each engaging block 5321 is located between the connecting edge 5834 and the transition edge 5832, the engaging block 5321 is rotated about the axis from the first slanted edge 5762 to the second slanted edge 5763, until passing though the second slanted edge 5763 and abuts a next (third) adjacent first slanted edge 5762. Simultaneously, each engaging block 5321 is moved to a next positioning slot 585 along the transition edge 5832, until reaching the corresponding positioning slot 585. The resilient component 59 is completely released, to move the engaging member 53 and the engaging rod 55 upward. The drive member 57 is thus moved upward by the engaging member 53, and each engaging block 5331 pushes each first slanted edge 5762 to move each protruding block 5751 to slide upward in the corresponding positioning slot 585, until the protruding block 5751 is positioned in the top end of the corresponding positioning slot 585. Therefore, the drive member 57 can pull the post 553 to become removed from the securing hole 11, and the storage device 10 can be removed from the enclosure 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
an enclosure defining a mounting hole; and
a mounting device attached to the enclosure, the mounting device comprising:
a receiving member defining a positioning slot and a cutout, the cutout comprising an oblique edge, the oblique edge comprising a first end and a second end, and the first end connected to a first edge of the positioning slot;
a drive member moveably received in the receiving member; the drive member comprising a driving portion, the driving portion comprising a first slanted edge, a second slanted edge, and a stopping portion connected to the first slanted edge and the second slanted edge, and an extending direction of the first slanted edge is the same as that of the oblique edge;
an engaging member comprising an engaging block received in the positioning slot, abutting the first slanted edge and away from the stopping portion;
an engaging rod defining an axis; and
a resilient member surrounding the engaging rod;
wherein the first slanted surface drives the engaging block to disengage from the positioning slot along the axis; when the engaging block is disengaged from the first edge of the positioning slot and reaches the first end of the oblique edge, the resilient member is deformed, and the engaging rod extends through the mounting hole and is received in an securing hole of a storage device; the resilient member is released to rotate the drive member and the engaging rod relative to the receiving member about the axis, and the engaging block is rotatable along the oblique edge to engage in the second end of the oblique edge.

2. The mounting apparatus of claim 1, wherein the drive member comprises a protruding block, and the protruding block is slidably received in the positioning slot.

3. The mounting apparatus of claim 2, wherein the drive member comprises a bottom plate and a side plate connected to the bottom plate, the bottom plate comprises a resisting portion, the driving portion is defined in the resisting portion, and the protruding block is located on the side plate and adjacent to the resisting portion.

4. The mounting apparatus of claim 1, wherein the engaging block comprises a slanted surface, and the slanted surface abuts the first slanted edge.

5. The mounting apparatus of claim 1, wherein a length of the second slanted edge is substantially equal to that of the first slanted edge, and the first slanted edge and the second slanted edge cooperatively define an obtuse angle.

6. The mounting apparatus of claim 3, wherein the receiving member defines a transition edge connected to a second opposite edge of the positioning slot, the cutout further comprises a connecting edge connected to the oblique edge and the transition edge.

7. The mounting apparatus of claim 1, wherein the engaging rod comprises a head and a post connected to the head, the head is received in the receiving member, and the resilient member is attached to the post.

8. The mounting apparatus of claim 1, wherein the engaging member comprises a base and a retaining portion connected to the base, the engaging block extends from the base and abuts an outer surface of the retaining portion.

9. The mounting apparatus of claim 1, wherein the mounting device further comprises a mounting member, the resilient member abuts the mounting member, the mounting member defines a through hole communicating with the mounting hole, when the engaging block is clipped in the cutout, the post is received in the through hole, and when the engaging block is disengaged from the cutout, the post is exposed out of the through hole.

10. A mounting apparatus comprising:
an enclosure defining a mounting hole; and
a mounting device comprising:
a mounting member attached to the enclosure and defining a through hole communicating with the mounting hole;
a receiving member defining a positioning slot and a cutout, the cutout comprising an oblique edge, the oblique edge comprising a first end and a second end, and the first end connected to a first edge of the positioning slot,
a drive member moveably received in the receiving member; the drive member comprising a driving portion, the driving portion comprising a first slanted edge, a second slanted edge, and a stopping portion connected to the first slanted edge and the second slanted edge, and an extending direction of the first slanted edge is same as that of the oblique edge;
an engaging member comprising an engaging block abutting the first slanted edge and away from the stopping portion;
an engaging rod defining an axis substantially perpendicular to the enclosure and
a resilient member surrounding the engaging rod;
wherein the engaging member is movable about the axis relative to the receiving member in an unlocked position, an locked position, and a middle position between the unlocked position and the locked position;
in the unlocked position, the resilient component is in an original state, the engaging block abuts the first slanted edge and away from the stopping portion, and the drive member is exposed out of the receiving member;
in the middle position, the drive member is received in the receiving member, the resilient component is deformed, the engaging block is located the first end of the oblique edge, and the engaging rod extends through the through hole and mounting hole, to engage in a securing hole of a storage device;
in the locked position, the drive member is exposed out of the receiving member, the resilient component is deformed, the engaging block is engaged in the second end of the oblique edge, abutting the first slanted edge and away from the stopping portion, to prevent the engaging rod from disengaging from the securing hole.

11. The mounting apparatus of claim 10, wherein the drive member comprises a protruding block, and the protruding block is slidably received in the positioning slot.

12. The mounting apparatus of claim 11, wherein the drive member comprises a bottom plate and a side plate connected to the bottom plate, the bottom plate comprises a resisting portion, the driving portion is defined in the resisting portion, and the protruding block is located on the side plate and adjacent to the resisting portion.

13. The mounting apparatus of claim 10, wherein the engaging block comprises a slanted surface with an extending direction the same as the oblique edge, and the slanted surface abuts the first slanted edge.

14. The mounting apparatus of claim 10, wherein a length of the second slanted edge is substantially equal to that of the first slanted edge, and the first slanted edge and the second slanted edge cooperatively define an obtuse angle.

15. The mounting apparatus of claim 10, wherein the receiving member defines a transition edge connected to a second opposite edge of the positioning slot, and the cutout further comprises a connecting edge connected to the oblique edge and the transition edge.

16. The mounting apparatus of claim 10, wherein the engaging rod comprises a head and a post connected to the head, the head is received in the receiving member, and the resilient member is attached to the post.

17. The mounting apparatus of claim 10, wherein the engaging member comprises a base and a retaining portion connected to the base, and the engaging block extends from the base and abuts an outer surface of the retaining portion.

18. The mounting apparatus of claim 17, wherein a diameter of the base is greater than that of the retaining portion.

19. The mounting apparatus of claim 10, wherein the drive member comprises a circular cross-section.
